(19) United States
(12) Patent Application Publication
(10) Pub. No.: US 2013/0163199 A1
(43) Pub. Date: Jun. 27, 2013

(54) ELECTRONIC DEVICE UTILIZING AIR GUIDER

(71) Applicant: LI-PING CHEN, Tu-Cheng (TW)

(72) Inventor: LI-PING CHEN, Tu-Cheng (TW)

(73) Assignee: HON HAI PRECISION INDUSTRY CO., LTD., Tu-Cheng (TW)

(21) Appl. No.: 13/437,951

(22) Filed: Apr. 3, 2012

(30) Foreign Application Priority Data
Dec. 27, 2011 (TW) 100149037

(51) Int. Cl. H05K 7/20

(52) U.S. Cl. 361/690

(57) ABSTRACT

An electronic device includes a main board, a plurality of add-on cards, a bracket mounted above the add-on cards, and an air guider. The add-on cards are mounted on the main board and spaced apart from each other. The add-on cards define a plurality of channels therebetween. The air guider includes a plurality of baffles pivotally connected to a bottom of the bracket, and a plurality of elastic members. Each of the elastic members pushes a corresponding baffle to contact a top of a corresponding add-on card to baffle air flowing between the bracket and the top of the corresponding add-on card and direct such air flowing through the channels.

### BACKGROUND

1. Technical Field

The present disclosure relates to electronic devices, and more particularly to an electronic device using heat dissipation device with an air guider.

2. Description of the Related Art

In order to enable electronic devices such as desktop and other computers to rapidly process graphics and games, add-on units, generally referred to as “graphics cards” or “VGA cards”, are often installed in computer devices. Such cards comprise a separate processor, called a GPU (graphics processor unit). The GPU generates a large amount of heat during operation. When the temperature of the GPU exceeds a certain level, the GPU may be in malfunction, or in the worst case fail outright.

For this reason, a heat dissipation device with heat sinks is commonly installed on the GPU to dissipate the heat generated by the GPU and other electronic components adjacent to it into ambient air. Generally, a system fan is installed at a lateral side of an enclosure of the electronic device. Air is generated by the system fan to flow through channels of the heat sinks, thereby taking the heat away. The heat dissipation device commonly includes air guiders mounted between the VGA cards and the electronic device to direct all air toward the channels of the heat sinks However, to conform to different VGA cards, different sizes of air guiders are needed, with correspondingly different sizes of air guiders, resulting in increasing manufacturing costs.

It is thus desirable to provide an electronic device which can overcome the described limitations.

### BRIEF DESCRIPTION OF THE DRAWINGS

The components of the drawings are not necessarily drawn to scale, the emphasis instead being placed upon clearly illustrating the principles of the embodiments of the display device. Moreover, in the drawings, like reference numerals designate corresponding parts throughout several views.

FIG. 1 is an isometric, assembled view of an electronic device in accordance with an embodiment of the present disclosure.

FIG. 2 is an isometric, exploded view of the electronic device of FIG. 1.

FIG. 3 is an isometric view of a bracket and a guiding module of the electronic device of FIG. 1, showing the bracket and the guiding module inverted.

FIG. 4 is an enlarged view of a circled portion IV of FIG. 3.

FIG. 5 is a cutaway view of the electronic device along a line V-V of FIG. 1, wherein a guiding module of the electronic device is located in a first position.

FIG. 6 is similar to FIG. 5, but showing the guiding module of the electronic device located in a second position.

### DETAILED DESCRIPTION

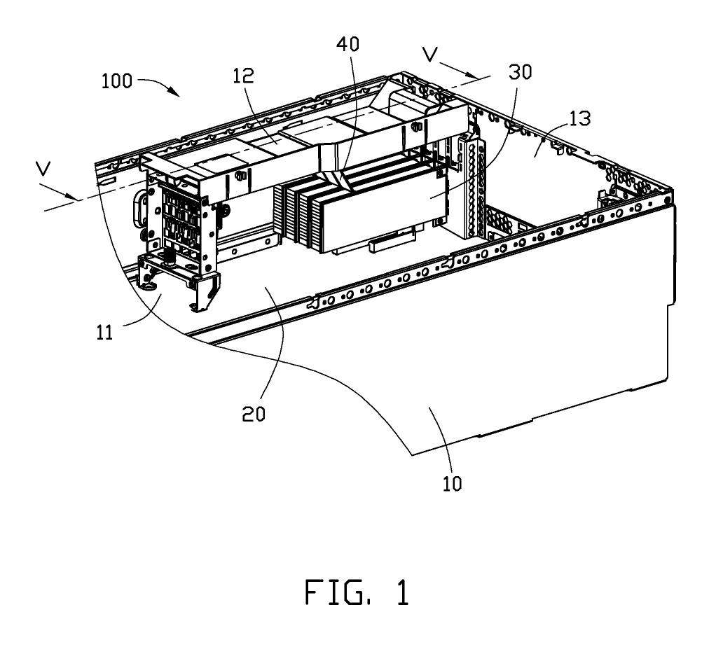

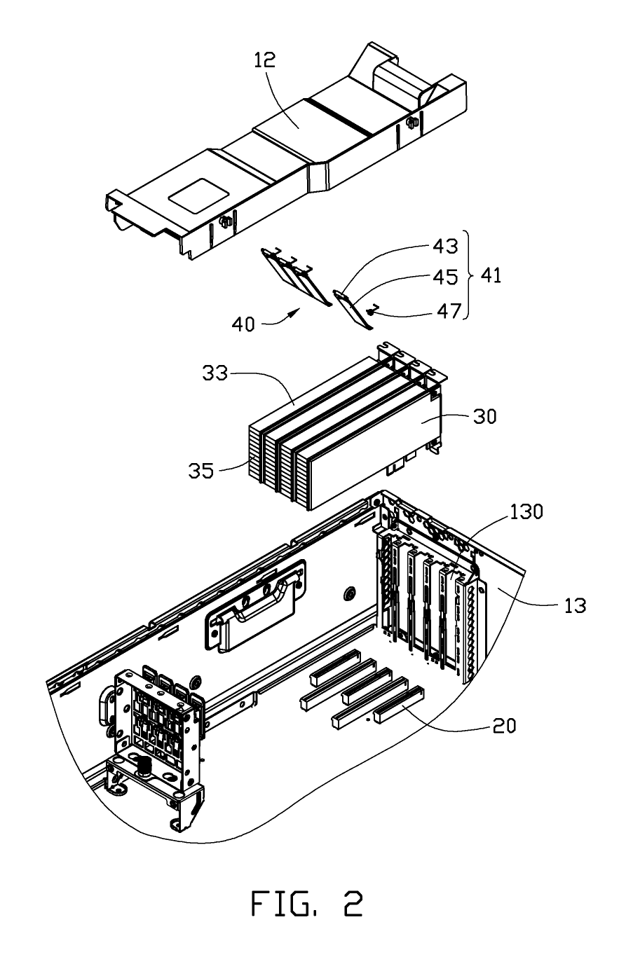

Referring to FIGS. 1-2, an electronic device 100, such as a computer, is shown. The electronic device 100 includes an enclosure 10, a main board 20 mounted in the enclosure 10, a plurality of add-on cards 30 installed on the main board 20, and an air guiding module 40 abutting on tops of the add-on cards 30.

The enclosure 10 includes a bottom plate 11 and a plurality of side plates 13 upwardly extending from the bottom plate 11. One of the side plates 13 defines a plurality of outlets 130 spatially corresponding to ends of the add-on cards 30. The main board 20 is mounted on the bottom plate 11. The add-on cards 30 are perpendicularly installed on the main board 20. The enclosure 10 includes a bracket 12 connected to side plates 13 and located above the add-on cards 30. Each of the add-on cards 30 includes a heat generating electronic member thereon and a heat sink 33 mounted on the heat generating electronic member. The heat sink 33 defines a plurality of parallel channels 35 communicating an inner of the enclosure 10 and the outlets 130 of the side plate 13. The electronic device 100 includes a system fan (not shown) generating air to flow through the channels 35 of the heat sink 33.

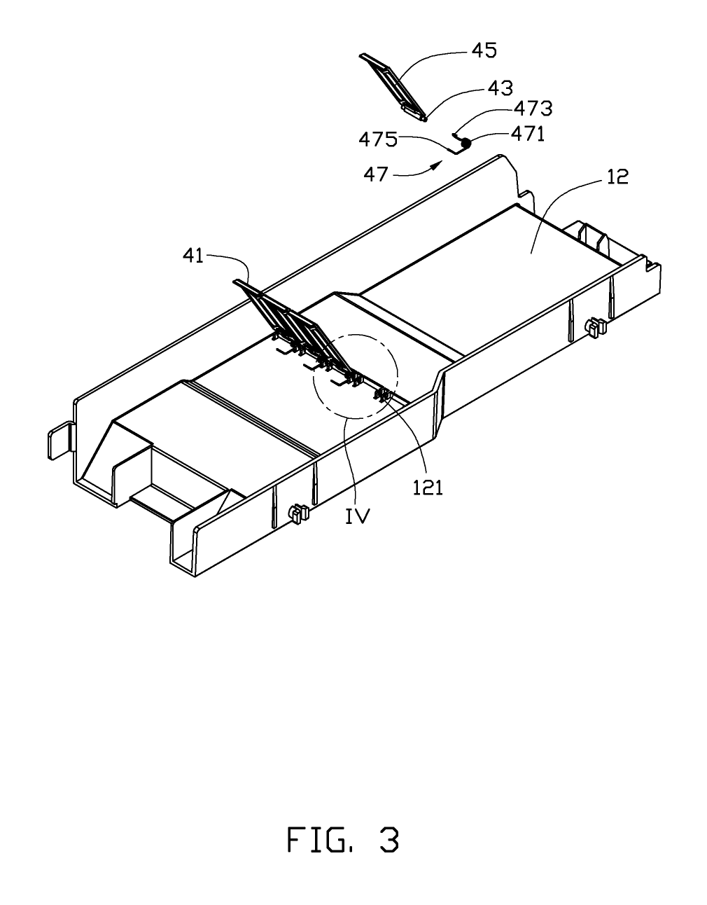

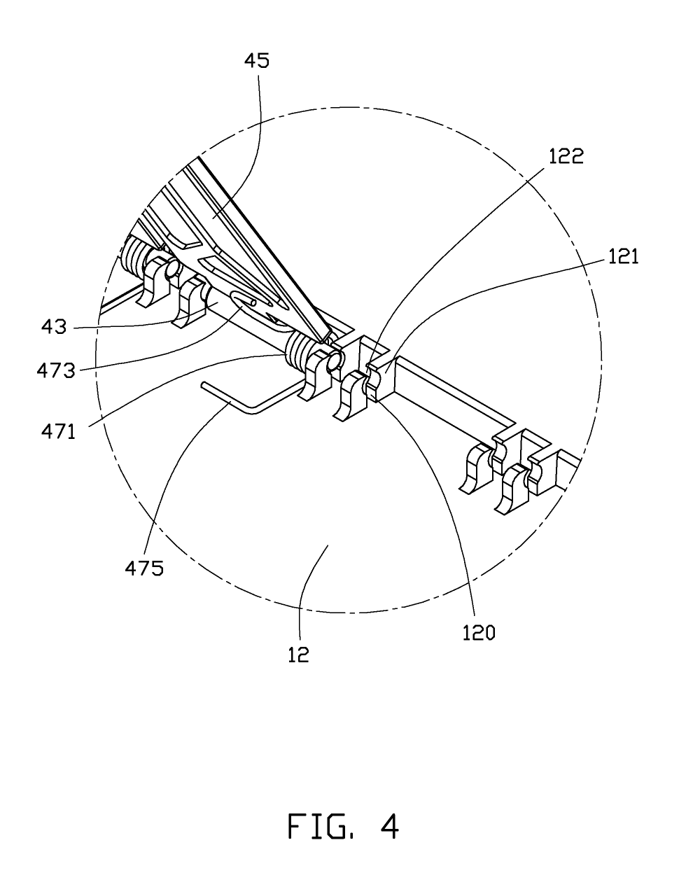

Referring also to FIGS. 3-4, the air guiding module 40 includes a plurality of guiders 41 pivotally connected to a bottom of the bracket 12. The guiders 41 are juxtaposed to each other and abut against the tops of the add-on cards 30. Each of the guiders 41 includes a baffle 45, a shaft 43 formed at a top end of the baffle 45, and an elastic member 47 such as a spring coiling around the shaft 43. The baffle 45 is a rectangular plate with a curved bottom end to facilitate contacting on the add-on card 30. The elastic member 47 is a torsion spring in the present embodiment. The elastic member 47 includes an annular body 471, an operating portion 473 and a blocking portion 475 respectively extending from two ends of the annular body 471. The baffle 45 of each guider 41 contacts a top of the corresponding heat sink 33 to direct air flowing through the channels 35 of the heat sink 33, thereby taking heat generated by the heat generating electronic member away.

The bracket 12 includes a plurality of connecting walls 121 pivotally engaged with the guiders 41. Each of the connecting walls 121 defines a pivot hole 120 to receive ends of the baffle 45. In the illustrated embodiment, each of the connecting walls 121 defines a slit 122 communicating the pivot hole 120. The baffle 45 is pressed through the slit 122 to be received in the pivot hole 120. The shaft 43 of each of the baffles 45 has a diameter slimily larger than a width of the slit 122 of the connecting wall 121.

In assembly, the shaft 43 of each guider 41 is coiled with the elastic member 47 and then pivotally engaged in two pivot holes 120 of the connecting walls 121. The blocking portion 475 of the elastic member 47 contacts the bottom of the bracket 12. Simultaneously, the operating portion 473 abuts against a back surface of the baffle 45. The blocking portion 475 and the operating portion 473 cooperatively define an acute angle. The elastic member 47 provides a force to push the baffle 45 away from the bracket 12 and towards the corresponding heat sink 33 and the add-on card 30.

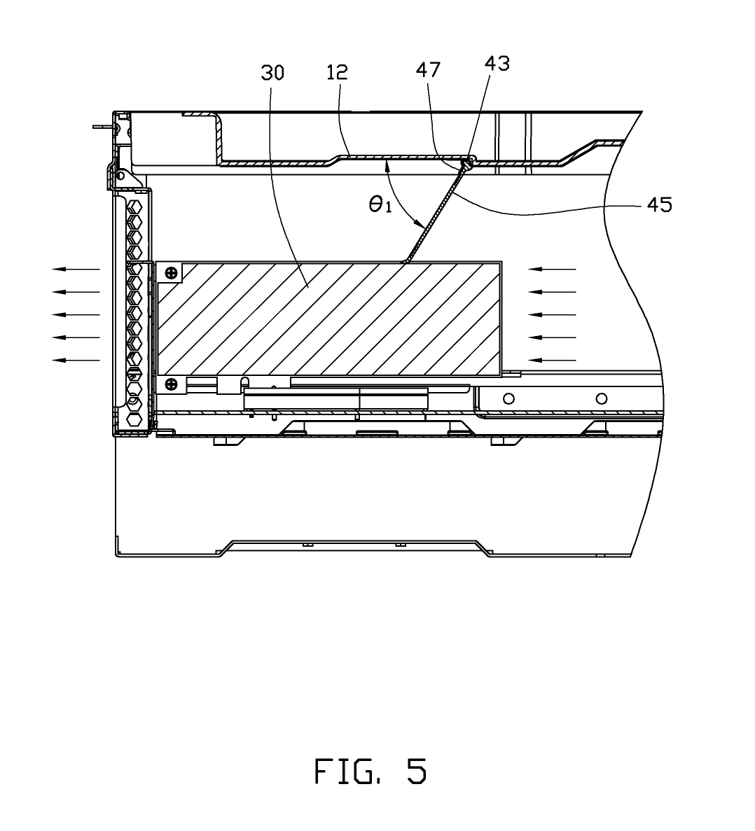

Referring to FIG. 5, when the baffle 45 of each guider 41 is in a first position, the baffles 45 of the guiders are pushed by the elastic members 47 to contact the heat sinks 33 to baffle air flowing between the bracket 12 and the tops of the add-on cards 30 and directs such air flowing through the channels 35 of the heat sinks 33. Each of the baffles 45 defines an angle θ1 with the bottom of the bracket 12.

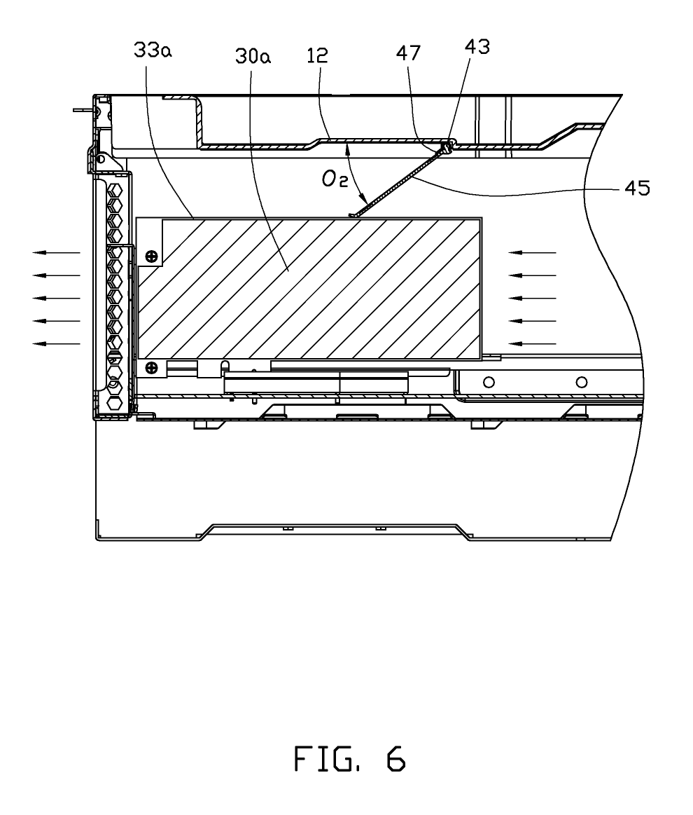

Referring to FIG. 6, when new add-on cards 30a with heat sinks 33a presents a height different from that of the add-on cards 30 with the heat sinks 33, the baffles 45 are adjusted from the first position to a second position. Each of the baffles 45 is defined at a new angle θ₂ with the bottom of the bracket 12. Alternatively, the electronic device 100 can include different add-on cards 30, 30a with different height, and the baffles 45 can be in the first position or in the second position to satisfy the corresponding add-on card 30/30a. Accordingly, the baffles 45 of the air guiding module 40 contacts tops of different add-on cards 30, 30a to baffle air flowing between the bracket 12 and the tops of the add-on cards 30, 30a and directs such air flowing through the heat sinks 33, 33a.

It is to be further understood that even though numerous characteristics and advantages have been set forth in the foregoing description of the embodiment(s), together with details of the structures and functions of the embodiment(s), the disclosure is illustrative only; and that changes may be made in detail, especially in the matters of shape, size, and arrangement of parts within the principles of the disclosure to the full extent indicated by the broad general meaning of the terms in which the appended claims are expressed.

What is claimed is:

1. An electronic device comprising:
a main board;
a plurality of add-on cards mounted on the main board and spaced apart from each other, the add-on cards defining a plurality of channels therebetween;
a bracket mounted above the add-on cards; and
an air guider comprising a plurality of baffles pivotally connected to a bottom of the bracket, and a plurality of elastic members, each of the elastic members pushing a corresponding baffle to contact a top of a corresponding add-on card to baffle air flowing between the bracket and the top of the corresponding add-on card and direct such air flowing through the channels.

2. The electronic device of claim 1, wherein the bracket comprises a plurality of connecting walls defining pivot holes, the baffles each having a shaft pivotally engaged in two pivot holes of the connecting walls.

3. The electronic device of claim 2, wherein each of the connecting walls defines a slit communicating the pivot hole, each shaft extending through two corresponding slits to be received in the two pivot holes.

4. The electronic device of claim 3, wherein the shaft of each of the baffles has a diameter slimily larger than a width of the slit of the corresponding connecting wall.

5. The electronic device of claim 2, wherein each of the elastic members is a torsion spring comprising an annular body sleeved over the shaft, an operating portion and a blocking portion respectively extending from two ends of the annular body, the blocking portion contacting the bottom of the bracket, and the operating portion abutting against the baffle to push the baffle to contact the top of the corresponding add-on card.

6. The electronic device of claim 1, wherein the add-on cards comprise a plurality of heat sinks, the channels being defined in the heat sinks.

7. The electronic device of claim 1, further comprising an enclosure receiving the main board, the add-on cards and the air guider, wherein the enclosure defines outlets communicating the channels between the add-on cards.

8. An electronic device comprising:
an enclosure comprising a bottom plate and a plurality of side plates connecting the bottom plate;
a main board with a plurality of add-on cards mounted in the enclosure, the add-on cards defining a plurality of channels;
a bracket mounted in the enclosure and located above the add-on cards; and
a plurality of baffles pivotally connected to a bottom of the bracket, each of the baffles arranged in an angle with the bottom of the bracket and being rotatable relative to the bracket to adjust the angle between the baffle and the bracket to abut on the add-on cards.

9. The electronic device of claim 8, wherein the bracket comprises a plurality of connecting walls, each connecting wall defining a pivot hole, the baffles each having a shaft pivotally engaged in two pivot holes of the connecting walls.

10. The electronic device of claim 9, wherein each of the connecting walls defines a slit communicating the pivot hole, each shaft extending through two corresponding slits to be received in the two pivot holes.

11. The electronic device of claim 10, wherein the shaft of each of the baffles has a diameter slimily larger than a width of the slit of the corresponding connecting wall.

12. The electronic device of claim 9, wherein each of the elastic members is a torsion spring comprising an annular body sleeved over the shaft, an operating portion and a blocking portion respectively extending from two ends of the annular body, the blocking portion contacting the bottom of the bracket, and the operating portion abutting against the baffle to push the baffle to contact the top of the corresponding add-on card.

13. The electronic device of claim 8, wherein the add-on cards comprise a plurality of heat sinks, the channels being defined in the heat sinks.

14. The electronic device of claim 8, wherein the enclosure defines outlets communicating the channels between the add-on cards.
